(19) United States
(12) Patent Application Publication
(10) Pub. No.: US 2005/0194625 A1
(43) Pub. Date: Sep. 8, 2005

(54) Semiconductor device, method of fabricating the same, and memory device

(75) Inventor: Takashi Nakagawa, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/068,809

(22) Filed: Mar. 2, 2005

(30) Foreign Application Priority Data
Mar. 2, 2004 (JP) 2004-057391

(51) Int. Cl. H01L 29/76; H01L 21/00

(52) U.S. Cl. 257/295; 438/3

(57) ABSTRACT

This invention is to provide a semiconductor device using ferroelectric material, having Perovskitic crystal structure expressed by the general formula ABO₃, and capable of giving a desirable residual polarization value and I-V characteristics when adopted as a capacitor element. The semiconductor device uses a ferroelectric material 2 having Perovskitic crystal structure expressed by the general formula ABO₃, wherein the compositional ratio (A)/(B) of the element A and element B is adjusted to the range satisfying the specific formula.

This application is based on Japanese patent application No. 2004-057391 the content of which is incorporated hereinto by reference.

### DISCLOSURE OF THE INVENTION

1. Field of the Invention

The present invention relates to a semiconductor device, a method of fabricating the same, and a memory device.

2. Related Art

Much effort has been directed to recent research and development of ferroelectric material memories and so forth which make use of polarization property of ferroelectric material.

Known methods of forming film of ferroelectric material conventionally adopted include sol-gel process, sputtering process, CVD process and so forth. Among others, the CVD process is promising as a mass-production technology for ULSI (ultra large scale integration) by virtue of its excellent uniformity in the film formation over large-diameter wafers, and its excellent step coverage.

One of ever-known ferroelectric material is such as composed of Perovskitic crystal expressed by ABO₃.

One known example is a ferroelectric capacitor layer Pb(Zr,Ti)O₃ (referred to as PZT capacitor, hereinafter) which contains Pb (lead) as the element A, and Zr (zirconium) and Ti (titanium) as the element B. It has generally been believed that compositional ratio (A)/(B) of the element A and element B in the PZT capacitor, or compositional ratio (Pb)/((Zr)+(Ti)), is preferably 1.0, which is a stoichiometric ratio.

Japanese Laid-Open Patent Publication “Tokkai” No. 2002-76292 discloses an exemplary technique in which the ABO₃ ferroelectric material is the PZT capacitor, and the compositional ratio (Pb)/((Zr)+(Ti)) satisfies the formula (11) below:
1.0<(Pb)/((Zr)+(Ti))≦1.1 (11)

Japanese Laid-Open Patent Publication “Tokkai” No. 2002-76292 describes that thus-adjusted compositional ratio makes it possible to obtain an excellent ferroelectric characteristic.

The reason why the compositional ratio (A)/(B) described in Japanese Laid-Open Patent Publication “Tokkai” No. 2002-76292 is set to a value larger than the stoichiometric ratio, as expressed by the formula (11) in the above, is supposed to be a result of consideration that Pb may partially be lost from the ferroelectric material layer in the post-processes.

There is, however, still a room for improving the PZT capacitor having the compositional ratio within the range expressed by the formula (11) in view of residual polarization value, which is an electrical characteristic of capacitor.

### SUMMARY OF THE INVENTION

Ferroelectric material having Perovskitic crystal structure expressed by the general formula ABO₃ can be exemplified by PZT, as described in the above.

A Pb organo-metallic material gas, which is a Pb source for the element A in this case, is decomposed on the surface of PZT, and oxidized to thereby produce PbO. Because of a small adhesion coefficient of such PbO on the surface, the Pb organo-metallic material gas merely supplied over the PZT surface will, however, not result in formation of a film thereon.

Whereas, supply of Ti and Zr, together with the Pb organo-metallic material gas, over the PZT surface will allow PbO on the surface to bond with Ti or Zr before being released into the vapor phase, and immobilized on the surface (film formation can be carried out).

A portion of Pb unbondable with Ti and Zr will therefore be released into the vapor phase even if the gas is supplied in a certain excessive amount. This sort of vapor phase growth can establish a self-control region (self-adjusted region) where the stoichiometric ratio coincides.

Referring now to an exemplary case of vapor-phase growth of PZT, the self-control region herein means a region where ratio of increase in the compositional ratio (Pb)/((Zr)+(Ti)) with respect to increase in the ratio of supply of Pb source to the total supply volume (total flow rate) of Pb, Ti and Zr sources is relatively small (as compared with other regions).

FIG. 3 is a graph showing measured results of the compositional ratio (Pb)/((Zr)+(Ti)) plotted against varied ratio of Pb flow rate in the vapor-phase growth, where the ordinate plots the compositional ratio (Pb)/((Zr)+(Ti)), and the abscissa plots the “flow rate of Pb source”/“total flow rate (including flow rates of the individual sources of Pb, Ti and Zr)”. As indicated by the hatched region in FIG. 3, the graph shows a moderate slope in the self-control region as compared with that in other regions.

Considering the above, the present inventors have discussed, as described below, a reason for lowering in the residual polarization value, which is an electrical characteristic of the capacitor, and degradation in the I-V characteristic (degraded voltage resistance) of the PZT capacitor (Japanese Laid-Open Patent Publication “Tokkai” No. 2002-76292) having the compositional ratio within the range expressed by the formula (11).

For the case where a PZT film is formed, for example, on a Ru electrode by the vapor phase growth process, the above-described compositional range expressed by the formula (11) resides on the Pb-excessive side of the self-control region of the compositional ratio (Pb)/((Zr)+(Ti)) with respect to the ratio of Pb flow rate.

When the ratio of Pb flow rate increases to thereby raise surface density (density on the surface of PZT) of PbO, it seems to be feasible enough that PbO can react with one another on the surface of PZT, to thereby allow PbO crystal to deposit due to excessive Pb.

In other words, for the case of PZT capacitor having the compositional ratio within the range expressed by the formula (11) (Japanese Laid-Open Patent Publication “Tokkai” No. 2002-76292), the lowering in the residual polarization characteristic, which is an electrical characteristic of the capacitor, and degradation in the I-V characteristic (lowered voltage resistance) are supposed to occur as a result of deposition of PbO crystal.

The present inventors then investigated into relation of the ratio of Pb flow rate with compositional ratio (Pb)/((Zr)+(Ti)) in the vapor-phase growth of the PZT capacitor, and confirmed that rate of increase in the compositional ratio (Pb)/((Zr)+(Ti)) with respect to increase in the ratio of Pb flow rate becomes small (i.e., the self-control region appears) in the compositional range expressed by the formula (8) below, where the residual polarization value of the PZT capacitor becomes maximum.
0.65≦(Pb)/((Zr)+(Ti))<1.0 (8)

This suggests that the film formation can be carried out under self-control of the composition, in the range expressed by the formula (8) in the above.

In other words, it is supposed that the deposition of PbO due to excessive Pb, which is one of reasons causative of degradation in the capacitor characteristic, can be suppressed in a self-adjusted manner, and this consequently maximizes the residual polarization value indicating the electrical characteristic of the capacitor.

According to the present invention, there is provided, based on the investigation results, a semiconductor device using a ferroelectric material having Perovskitic crystal structure expressed by general formula ABO₃, wherein the ferroelectric material has a compositional ratio (A)/(B) of element A and element B contained therein, set within a range satisfying the formula (1):
0.65≦(A)/(B)<1.0 (1)

In the semiconductor device of the present invention, the compositional ratio (A)/(B) may be set within a range satisfying the formula (2):
0.65≦(A)/(B)≦0.95 (2)

In the semiconductor device of the present invention, the compositional ratio (A)/(B) may be set within a range satisfying the formula (3):
0.65≦(A)/(B)≦0.90 (3)

An example of the semiconductor device of the present invention comprises PZT which contains lead (Pb) as the element A, and contains zirconium (Zr) and titanium (Ti) as the element B.

That is, the compositional ratio (A)/(B) in this case is expressed as (Pb)/((Zr)+(Ti)), the formula (1) can be expressed as the formula (8), the formulas (2) and (3) can be expressed as the formula (9) and (10), respectively.
0.65≦(Pb)/((Zr)+(Ti))≦0.95 (9)
0.65≦(Pb)/((Zr)+(Ti))≦0.90 (10)

According to another aspect of the present invention, there is provided a method of fabricating a semiconductor device using a ferroelectric material having Perovskitic crystal structure expressed by general formula ABO₃, wherein, assuming sources of element A and element B, supplied during film formation of the ferroelectric material, as a source A and a source B, respectively, and amounts of supply of the element A and the element B as amount A and amount B, respectively, a film of the ferroelectric material is formed while setting ratio of supply amount of the source A to the total of supply amounts of the source A and the source B “amount A/(amount A+amount B)” to a value not higher than the upper limit of a self-control region where ratio of increase in the compositional ratio (A)/(B) with respect to increase in the ratio of supply amounts “amount A/(amount A+amount B)” is relatively small.

In the method of fabricating a semiconductor device of the present invention, the film of ferroelectric material may be formed while setting the ratio of supply amounts “amount A/(amount A+amount B)” to a value not higher than the lower limit of the self-control region.

In the method of fabricating a semiconductor device of the present invention, the film of the ferroelectric material may be formed by a vapor-phase growth process under a pressure condition of not less than 6.65 Pa and not more than 532 Pa.

In the method of fabricating a semiconductor device of the present invention, the film of the ferroelectric material may be formed by a vapor-phase growth process under a pressure condition of not less than 6.65 Pa and not more than 266 Pa.

In the method of fabricating a semiconductor device of the present invention, the film of the ferroelectric material may be formed by a vapor-phase growth process under a pressure condition of not less than 6.65 Pa and not more than 133 Pa.

According to still another aspect of the present invention, there is also provided a semiconductor device obtained by these fabrication methods.

According to still another aspect of the present invention, there is also provided a semiconductor device configured as a capacitor element which comprises the ferroelectric material layer, and a lower electrode and an upper electrode arranged so as to hold the ferroelectric material layer in between.

In the semiconductor device of the present invention, the lower electrode may be composed of ruthenium (Ru).

In the semiconductor device of the present invention, the upper electrode may be composed of ruthenium oxide.

In the semiconductor device of the present invention, the lower electrode may have a film composed of at least any one material selected from platinum (Pt), iridium (Ir), ruthenium (Ru) and oxides of these elements, formed at least on the surface thereof for the ferroelectric material layer side.

In the semiconductor device of the present invention, the upper electrode may have a film composed of at least any one material selected from platinum (Pt), iridium (Ir) ruthenium (Ru) and oxides of these elements, formed at least on the surface thereof for the ferroelectric material layer side.

According to the present invention, there is also provided a method of fabricating the semiconductor device of the present invention, comprising:
forming, on the lower electrode, a film of initial nuclei containing at least one metal element same as a metal element composing the ferroelectric material layer; and
forming the ferroelectric material layer on the initial nuclei,
carried out in this order.

According to the present invention, there is still also provided a method of fabricating the semiconductor device of the present invention, comprising:
forming, on the lower electrode, a film of initial nuclei containing at least one metal element same as a metal element composing the ferroelectric material layer;
forming, on the initial nuclei, a buffer layer containing at least one metal element same as a metal element contained in both of the initial nuclei and the ferroelectric material layer, in a ratio larger than that in the initial nuclei; and
forming the ferroelectric material layer on the buffer layer,
carried out in this order.

The initial nuclei and the buffer layer may be formed so as to contain the element A and the element B.

The initial nuclei and the buffer layer may be formed using lead titanium oxide (PTO) containing lead (Pb) as the element A and titanium (Ti) as the element B.

The initial nuclei may be formed so that the compositional ratio (B)/(A) of the element A and the element B contained therein satisfies the formula (6):
0.8≦(B)/(A)≦1.2 (6).

The initial nuclei may be formed so that the compositional ratio (B)/(A) of the element A and the element B contained therein satisfies the formula (7):
0.9≦(B)/(A)≦1.1 (7).

The initial nuclei may be formed to a thickness of 1 nm to 10 nm, and preferably of not less than 2 nm and not more than 10 nm.

The buffer layer may be formed so as to have a ratio of content of the element A larger than that of the initial nuclei.

The buffer layer may be formed so that the compositional ratio (B)/(A) of the element A and the element B contained therein satisfies the formula (4):
0.2≦(B)/(A)≦1.0 (4)

The buffer layer may be formed so that the compositional ratio (B)/(A) of the element A and the element B contained therein satisfies the formula (5):
0.4≦(B)/(A)≦0.8 (5)

The film of the initial nuclei may be formed so that the compositional ratio (B)/(A) of the element A and the element B contained therein satisfies the formula (6); and the buffer layer may be formed so that the compositional ratio (B)/(A) of the element A and the element B contained therein satisfies the formula (4):
0.8≦(B)/(A)≦1.2 (6)
0.2≦(B)/(A)≦1.0 (4)

The buffer layer may be formed to a thickness of not less than 0.2 nm and not more than 10 nm, preferably to a thickness of 0.4 nm or more, and still more preferably to a thickness of 1 nm or more. The buffer layer may be formed to a thickness of 8 nm or less, and more preferably to a thickness of 5 nm or less.

A film of the initial nuclei may be formed under a condition satisfying at least any one conditions lower in the temperature, and higher in the pressure, as compared with formation conditions of the ferroelectric material layer.

According to the present invention, there is provided a semiconductor device obtained by the method of these fabrication methods.

According to the present invention, there is further provided a memory device comprising the semiconductor device of the present invention.

In the present invention, the compositional ratio (A)/(B) of the element A and the element B contained in the ferroelectric material composing the semiconductor device is adjusted within the range satisfying the above formula (1). The range of the compositional ratio (A)/(B) expressed by the formula (1) includes a region (self-control region) where ratio of increase in the compositional ratio (A)/(B) with respect to increase in the flow rate of a source material composing the element A is small, and thereby the deposition of oxide of the element A (e.g., PbO) ascribable to an excessive element A (e.g., excessive Pb), which is one cause for lowering the capacitor characteristic of the ferroelectric material, is suppressed in a self-controlled manner, and this consequently maximizes the residual polarization value indicating the electrical characteristic of the capacitor. In other words, a desirable residual polarization value can be obtained. A desirable I-V characteristic can also be obtained within the range which satisfies the above formula (1).

The present invention is therefore successful in providing a semiconductor device using a ferroelectric material, having Perovskitic crystal structure expressed by general formula ABO₃, and capable of achieving a desirable residual polarization value and I-V characteristic when applied as a capacitor element, a method of fabricating the same, and a memory device provided with the semiconductor device.

### BRIEF DESCRIPTION OF THE DRAWINGS

The above and other objects, advantages and features of the present invention will be more apparent from the following description taken in conjunction with the accompanying drawings, in which:

FIG. 1 is a sectional view showing a capacitor element owned by the semiconductor memory device according to an embodiment of the presetn invention;

FIG. 2 is a drawing showing Perovskitic crystal structure;

FIG. 3 is a drawing showing relations between compositional ratio (A)/(B) and ratio of flow rates of source materials in Example 1 according to an embodiment of the present invention;

FIG. 4 is a drawing showing relations between residual polarization value of the ferroelectric material layer and compositional ratio (A)/(B) in Example 1 according to an embodiment of the present invention;

FIG. 5 is a drawing showing relations between breakdown voltage (voltage resistance) of a capacitor element and compositional ratio (A)/(B) in Example 1 according to an embodiment of the present invention;

FIG. 6 is a drawing showing relations between leakage current value of a capacitor element and compositional ratio (A)/(B) in Example 1 according to an embodiment of the present invention;

FIGS. 7A and 7B are drawings showing characteristics of a ferroelectric material layer in Example 2 according to an embodiment of the present invention, wherein FIG. 7A shows relations between compositional ratio (A)/(B) and ratio of flow rates of the source materials, and FIG. 7B shows relations between residual polarization value of the ferroelectric material layer and compositional ratio (A)/(B);

FIGS. 8A and 8B are drawings showing characteristics of a capacitor element in Example 3 according to an embodiment of the present invention, wherein FIG. 8A shows a hysteresis characteristics, and FIG. 8B shows I-V characteristics;

FIGS. 9A and 9B are drawings showing characteristics of the capacitor element in Example 3 according to an embodiment of the present invention, wherein FIG. 9A shows a hysteresis characteristics, and FIG. 9B shows I-V characteristics;

FIGS. 10A and 10B are drawings showing characteristics of the capacitor element in Example 3 according to an embodiment of the present invention, wherein FIG. 10A shows a hysteresis characteristics, and FIG. 10B shows I-V characteristics; and

FIG. 11 is a drawing showing hysteresis characteristics in residual polarization value of the capacitor element in Example 4 according to an embodiment of the present invention.

### DETAILED DESCRIPTION OF THE INVENTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

The following paragraphs will describe embodiments of the present invention referring to the attached drawings.

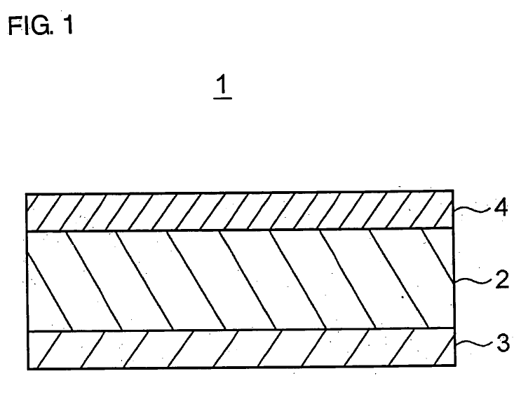

As shown in FIG. 1, a capacitor element (semiconductor device) 1 owned by a semiconductor memory device (memory device) according to a first embodiment comprises a ferroelectric material layer (ferroelectric material) 2, and a lower electrode 3 and an upper electrode 4 arranged so as to hold the ferroelectric material layer 2 in between.

The lower electrode 3 has, for example, initial nuclei (crystal nuclei) and a buffer layer (the both will be described later) formed thereon before the ferroelectric material layer 2 is formed.

The individual constituents of the capacitor element 1 will be described one by one.

(Ferroelectric Material Layer)

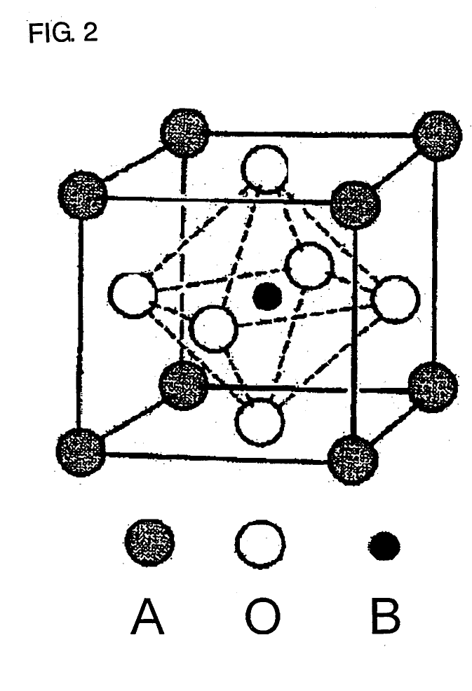

The ferroelectric material layer 2 has Perovskitic crystal structure (see FIG. 2) expressed by general formula ABO₃.

The compositional ratio (A)/(B) of the element A and element B contained in the ferroelectric material layer 2 is adjusted within the range satisfying the formula (1) below:
0.65≦(A)/(B)<1.0 (1)

The compositional ratio (A)/(B) may be further adjusted within the range satisfying the formula (2) below:
0.65≦(A)/(B)≦0.95 (2)

The compositional ratio (A)/(B) may be moreover adjusted within the range satisfying the formula (3) below:
0.65≦(A)/(B)≦0.90 (3)

Lead (Pb) may be employed for the element A which occupies lattice A (site A) in the Perovskitic crystal structure composing the ferroelectric material layer 2. In other words, the ferroelectric material layer 2 may be composed of a Pb-base dielectric. Among others, the ferroelectric material layer 2 may be composed of a PZT layer having zirconium (Zr) and titanium (Ti) as the element B which occupies lattice B.

Assuming now the ferroelectric material layer 2 is composed of a PZT layer, the above formula (1) can be replaced with the formula (8) below:
0.65≦(Pb)/((Zr)+(Ti))<1.0 (8)

That is, the compositional ratio (Pb)/((Zr)+(Ti)) of Pb, Zr and Ti contained in the ferroelectric material layer 2 is adjusted within the range satisfying the formula (8).

Similarly, the above-described formulae (2) and (3) can be replaced with the formulae (9) and formula (10), respectively.
0.65≦(Pb)/((Zr)+(Ti))≦0.95 (9)
0.65≦(Pb)/((Zr)+(Ti))≦0.90 (10)

That is, the compositional ratio (Pb)/((Zr)+(Ti)) is preferably adjusted within the range satisfying the above-described formula (9), and more preferably adjusted with the range satisfying the above-described formula (10).

(Electrodes)

The lower electrode 3 and upper electrode 4 may be those mainly composed of platinum (Pt), iridium (Ir), iridium oxide (IrO₂), ruthenium (Ru), ruthenium oxide (RuO, RuO₂), gold (Au), titanium nitride (TiN) and so forth.

In particular, Ru is preferable for the lower electrode 3, and ruthenium oxide (RuO, RuO₂) is preferable for the upper electrode 4.

These electrodes can be formed by CVD process, sputtering process, vacuum evaporation process and so forth.

The lower electrode 3 and upper electrode 4 preferably has a film composed of at least any one material selected from platinum (Pt), iridium (Ir), ruthenium (Ru) and oxides of these elements, formed at least on the surface thereof for the ferroelectric material layer side.

(Initial Nuclei)

The initial nuclei are provided on the lower electrode 3.

The initial nuclei contain at least one metal element same as that composing the ferroelectric material layer 2.

By providing the initial nuclei on the lower electrode 3 and then by forming the ferroelectric material layer 2 on the initial nuclei, it is made possible to form the ferroelectric material layer 2 improved in the orientation, crystallinity and inversion fatigue resistance and inversion fatigue toughness, as compared with those for the case where the ferroelectric material layer 2 is provided directly on the lower electrode 3.

In view of obtaining more excellent properties, the initial nuclei are preferably composed of the element A, element B and oxygen, and more preferably has Perovskitic crystal structure expressed by ABO₃.

The initial nuclei may be composed as containing all species of metal elements composing the ferroelectric material layer 2, or as containing only a part of those metal elements.

For an exemplary case where the ferroelectric material layer 2 is a PZT layer, the film of initial nuclei are preferably a PZT layer or a lead titanate (PTO) layer, and the PTO layer is more preferable in view of controllability in conditions for the film formation and crystallinity.

The compositional ratio of the element A and element B composing the initial nuclei B/A (compositional ratio (B)/(A) of the element A and element B contained in the initial nuclei: Ti/Pb for lead titanate) is preferably adjusted to 0.5 or more in view of the capacitor characteristics, more preferably 0.8 or more, and preferably 1.5 or less, more preferably 1.2 or less, and still more preferably within the range from 0.9 to 1.1.

Thickness of the film of the initial nuclei is preferably 1 nm or more in view of the capacitor characteristics, more preferably 2 nm or more, and preferably 10 nm or less.

Process time of formation of the initial nuclei can appropriately be adjusted typically within a range from 5 seconds to 60 seconds. Too short or long process time may result in difficulty in obtaining the dielectric film having desired characteristics.

The film of the initial nuclei is preferably formed under a condition satisfying at least any one conditions lower in the temperature, and higher in the pressure, as compared with those in formation conditions of the ferroelectric material layer 2.

(Buffer Layer)

The buffer layer is provided on the initial nuclei, and on the buffer layer, the ferroelectric material layer 2 is provided. It is to be understood that the buffer layer can be omitted as described later in Example 2, wherein the ferroelectric material layer 2 is directly provided on the initial nuclei.

The buffer layer necessarily contains at least one metal element same as a metal element contained in both of the initial nuclei and the ferroelectric material layer, in a ratio larger than that in the initial nuclei. It is preferable to adjust at least the ratio of contents of Pb and other high-vapor-pressure metal elements larger than the ratio of contents in the initial nuclei.

For the case where the initial nuclei contain any high-vapor-pressure metal element, a long waiting time between the formation processes of the initial nuclei and dielectric layer in the process of film formation by the MOCVD process makes it more likely to result in vaporization of the high-vapor-pressure metal element from the surface of the initial nuclei, and causes the deficiency. The stoichiometric defect portion formed by the deficiency ascribable to the deficiency will cause degradation in the capacitor characteristics.

In this embodiment, the buffer layer containing such high-vapor-pressure metal element which is likely to be deficient, and having its content larger than that in the initial nuclei is formed on the initial nuclei, and the ferroelectric material layer 2 is formed thereon. This makes it possible to improve the capacitor characteristics, in particular low-voltage characteristics as compared with the case having no buffer layer provided thereto.

In view of the capacitor characteristics, waiting time between the formation processes of the initial nuclei and buffer layer, and simplicity in the operations, the metal element composing the buffer layer is preferably selected from those composing the initial nuclei. In view of device characteristics, the buffer layer preferably contains at least one or more species of the element A and element B, respectively. For an exemplary case where the initial nuclei contains lead (Pb), the buffer layer preferably contains Pb, with the ratio of content of Pb larger than that in the initial nuclei. For another exemplary case where the ferroelectric material layer 2 is composed of PZT and the initial nuclei are composed of lead titanate, the buffer layer is preferably composed of lead titanate or lead oxide. Lead titanate is more preferable in view of the capacitor characteristic.

The ratio of content of the metal element in the buffer layer, which is desired to be prevented from eliminating from the surface of the initial nuclei, particularly the ratio of content of the high-vapor-pressure metal element, can appropriately be adjusted within a range larger than the ratio of content thereof in the initial nuclei. Too small ratio of content of the metal element in the buffer layer will fail in obtaining desired effects of improvement in the capacitor characteristics. On the contrary, too large ratio of content tends to degrade improving effect of the capacitor characteristics.

For an exemplary case where lead titanate is formed as a film of the initial nuclei, the buffer layer composed of lead oxide will be successful in obtaining improving effect of the capacitor characteristics.

For an exemplary case where lead titanate is formed as the initial nuclei and the buffer layer, and where Ti/Pb ratio of the initial nuclei (compositional ratio of titanium (Ti) and lead (Pb) contained in the initial nuclei) is approximately 1, or resides in a range typically from 0.8 to 1.2, and more preferably 0.9 to 1.1, a larger improving effect of the capacitor characteristics can be obtained by adjusting Ti/Pb ratio of the buffer layer (compositional ratio (Ti)/(Pb) of titanium (Ti) and lead (Pb) contained in the buffer layer) within a range typically from 0.2 to 1, and more preferably from 0.4 to 0.8.

Thickness of the buffer layer is preferably 0.2 nm or more, more preferably 0.4 nm or more, and still more preferably 1 nm or more, and on the other hand, 10 nm or less, more preferably 8 nm or less, and still more preferably 5 nm or less. Too thin buffer layer may fail in obtaining a desirable level of improving effect of the capacitor characteristics. On the contrary, too thick buffer layer will have too large influence on the crystal orientation property of the ferroelectric material layer 2 formed thereon, and may degrade the capacitor characteristics. It is therefore preferable for the buffer layer to have a thickness not affective to the crystal orientation of the ferroelectric material layer 2.

The buffer layer may be layered in two or more, wherein the buffer layers in such case can be layered so that the ratio of content of a high-vapor-pressure metal element such as Pb orderly increases from the lower electrode 3 towards the ferroelectric material layer 2. It is also allowable to configure the buffer layer as a layer having the ratio of content of a high-vapor-pressure metal element contained in the ferroelectric material layer 2, which increases continuously from the lower electrode 3 side towards the ferroelectric material layer 2.

(Film Formation by MOCVD Process)

The following paragraphs will specifically describe a method of forming the initial nuclei, buffer layer and ferroelectric material layer 2 by the MOCVD process. These constituents can be formed using a publicly-known vapor phase epitaxy apparatus for MOCVD.

Organometallic source materials employed for the MOCVD process can be introduced into a vacuum vessel (growth chamber), having a substrate housed therein, as being gasified under heating, and optionally together with a carrier gas.

Most of the organometallic source materials are solid or liquid under normal temperature and normal pressure. Those in solid state can be supplied based on the publicly-known solid sublimation system, or by the liquid transfer system in which the source materials are dissolved in an appropriate solvent and transported in the liquid state, and gasified by a gasifier placed in the preceding stage of the vacuum vessel. Those in liquid state can be supplied as they are, or as being optionally diluted with a solvent, based on the liquid transfer system.

The gasified source materials (source gases) are supplied over the substrate heated at a predetermined temperature in the vacuum vessel kept under a reduced pressure, and thereby the film formation is carried out. In view of controlling compositional ratio of the source gases, it is preferable herein to control temperature of the inner wall of the source material supply system and the vacuum vessel not lower than a level allowing the source materials to have a sufficient rate of detachment (vapor pressure) not causative of coagulation on the inner wall, and not higher than a level causative of decomposition. The temperature can be adjusted within a range typically from 180 to 220 degrees C. or around.

Examples of the organometallic source materials adoptable for production of PZT, for example, include lead bis-dipivaloyl methanate (Pb(DPM)₂) as the Pb source, titanium isopropoxide (Ti(OiPr)₄) and titanium diisopropoxy-bis-dipivaloyl methanate (Ti(OiPr)₂(DPM)₂) as the Ti sources; and zirconium butoxide (Zr(OtBu)₄) and zirconium isopropoxy-tris-dipivaloyl methanate (Zr(OiPr)(DPM)₃) as the Zr sources.

In view of preventing formation of an alloy or oxygen deficiency on the conductive layer composing the lower electrode 3, the organometallic source material gases are preferably supplied together with an oxidative gas. The oxidative gas can be exemplified by nitrogen dioxide (NO₂), ozone, oxygen, oxygen ion and oxygen radical, wherein nitrogen dioxide excellent in the oxidizing property is particularly preferable.

A further description will be made referring to the case where the initial nuclei and buffer layer composed of lead titanate, and the ferroelectric material layer 2 composed of PZT are formed using these source material gases.

First, a substrate having a conductive film composing the lower electrode formed thereon is placed in the vacuum vessel. The vacuum vessel is kept under a predetermined reduced-pressure condition, and temperature of the substrate is kept typically at 530 degrees C. or below. It is to be noted that the conditions for the film formation are not necessarily constant throughout the formation process of the initial nuclei, buffer layer and ferroelectric material layer 2, and it is also allowable, as described later, to form the initial nuclei at a relatively low temperature, and thereafter to form ferroelectric material layer 2 at a temperature higher than the formation temperature of the initial nuclei, or it is still also allowable to form the initial nuclei at a relatively high pressure, and thereafter to form the ferroelectric material layer 2 at a pressure lower than the formation pressure of the initial nuclei.

Next, a Pb source gas, a Ti source gas and an oxidative gas are supplied at predetermined flow rates for predetermined periods of time into the vacuum vessel, to thereby allow the initial nuclei to grow on the substrate (initial nuclei formation process). Thereafter the supply of the Pb source gas, Ti source gas and oxidative gas is terminated.

The formation of the initial nuclei may be preceded by the pretreatment process. For example, the Pb source gas and oxidative gas are supplied at predetermined flow rates for predetermined periods of time into the vacuum vessel (pretreatment process), supply of the Ti source gas is started while keeping the state unchanged, and this state is kept for a predetermined period of time, to thereby form the initial nuclei on the substrate (initial nuclei formation process).

The pretreatment process is necessarily carried out for a duration of time and under conditions which allow the Pb source gas to decompose on the surface of the conductive film to thereby fully react with the surface metal, and which can prevent formation of PbO film on the conductive layer. In view of fully obtaining a desired effect, for example, the process temperature (temperature of the conductive layer) is preferably adjusted to 350 degrees C. or above, and more preferably 390 degrees C. or above. On the other hand, in view of controlling the thermal degradation of aluminum interconnects and so forth, the process temperature is preferably adjusted to 700 degrees C. or below, more preferably 600 degrees C. or below, and still more preferably 500 degrees C. or below. The process time can appropriately be adjusted generally within a range of 60 seconds or shorter, and can typically be adjusted within a range from 3 seconds to 20 seconds. The formation of the PbO film herein can be confirmed by X-ray analysis.

The buffer layer is formed under a flow rate condition in which ratio of flow rates of the Pb source gas to the Ti source gas is larger than the ratio in the initial nuclei formation, and more specifically, the Pb source gas and the oxidative gas are supplied under the flow rate equivalent to, or substantially equivalent to that in the initial nuclei formation, and the Ti source gas is supplied under a flow rate smaller than that in the initial nuclei formation (buffer layer formation process). In this process, at least either one of the temperature and pressure may be optionally varied. After the elapse of a predetermined period of time, supply of the Pb source gas, Ti source gas and oxidative gas is terminated.

The supply conditions of the source materials are then varied, wherein the Pb source gas, Zr source gas, Ti source gas and oxidative gas are supplied under the individual flow rates, and the conditions are kept unchanged for a predetermined period of time, to thereby form the ferroelectric material layer 2 of a predetermined thickness (ferroelectric material layer formation process). In this process, at least either one of the temperature and pressure may be optionally varied. In view of preventing deficiency of any high-vapor-pressure metal element such as Pb in the formation process of the ferroelectric material layer, the waiting time between the formation processes of the buffer layer and the ferroelectric material layer is preferably as short as possible. For this purpose, the conditions for the buffer layer formation process (temperature, pressure) are preferably close as possible to those for the ferroelectric material layer formation process. This makes it possible to shorten stabilization time, or waiting time, for the ferroelectric material layer formation process.

After completion of the formation of the ferroelectric material layer 2, the conductive layer for forming the upper electrode is formed thereon by the sputtering process or CVD process.

(Film Formation Temperature and Pressure)

Total pressure of the source gases is preferably adjusted to 1×10⁻⁴ Torr (1.33×10⁻² Pa) or above, throughout the formation processes of the initial nuclei and the ferroelectric material layer, in view of the film growth rate. On the other hand, in the initial nuclei formation process, the total pressure can appropriately be adjusted to a range not higher than 100 Torr (13.3 kPa) in view of the crystallinity, and typically to 20 Torr (2.66 kPa) or below.

In the ferroelectric material layer formation process, the total pressure is preferably adjusted to 4 Torr (532 Pa) or below, more preferably 2 Torr (266 Pa) or below, and still more specifically within a range of 0.05 Torr (6.65 Pa) or above and 1.0 Torr (133 Pa) or below in view of the crystallinity.

Because the waiting time between the formation processes of the buffer layer and the ferroelectric material layer is preferably as short as possible in view of preventing deficiency of any high-vapor-pressure metal element such as Pb, the conditions for the buffer layer formation process (temperature, pressure) can appropriately be adjusted so as to be same as, or close to those for the ferroelectric material layer formation process, or in other words, within the range of process conditions for the ferroelectric material layer formation process.

Conditions for the initial nuclei formation process preferably satisfy at least either one of a condition characterized by a temperature (temperature of the ferroelectric material layer 2) lower than that in the ferroelectric material layer formation process (referred to as “low-temperature nucleation condition”, hereinafter), and a condition characterized by a source gas pressure higher than that in the ferroelectric material layer formation process (referred to as “high-pressure nucleation condition”, hereinafter). The method makes it possible to reduce the grain size of the dielectric layer foamed later, and to reduce the surface roughness. This is consequently successful in forming a dielectric film low in the leakage current, excellent in the transparency which facilitates the mask alignment. Use of such dielectric film to the capacitor element makes it possible to fabricate semiconductor devices having only a small variation in the bit line voltage difference. Because the waiting time between the formation processes of the buffer layer and the ferroelectric material layer is preferably as short as possible in view of preventing deficiency of any high-vapor-pressure metal element such as Pb, the conditions for the buffer layer formation process can appropriately be adjusted so as to be same as, or close to those for the ferroelectric material layer formation process, or in other words, within the range of process conditions for the ferroelectric material layer formation process.

(Method of Fabricating Semiconductor Memory Device)

Next paragraphs will describe a method of fabricating a semiconductor memory device having the capacitor element 1 which comprises the above-descried ferroelectric material layer 2, lower electrode 3 and upper electrode 4.

First, on a first insulating interlayer provided on the semiconductor substrate having active elements such as transistors formed thereon, the lower electrode 3 is formed. In this process, a TiN film or a layered film of Ti and TiN (e.g., Ti/TiN/Ti layered film), for example, is formed as a barrier film by the sputtering process, and further thereon, a conductive film of 100 nm thick or around typically composed of Ru is formed as the lower electrode by the sputtering process or the CVD process.

Patterning for forming the lower electrode 3 may be carried out after the formation of the conductive film, or may be carried out en bloc after the formation of the ferroelectric material layer 2 and a dielectric film forming the upper electrode 4. The lower electrode 3 is arranged so as to electrically be connected to plugs which are provided in the first insulating interlayer and electrically connected to the active elements.

Next, on the conductive film for forming the lower electrode or on thus-patterned lower electrode 3, a film of the initial nuclei, buffer layer, and ferroelectric material layer 2 are formed in this order by the MOCVD process according to the above-described procedures.

Next, on the ferroelectric material layer 2, a conductive film of 100 nm thick or around typically composed of an oxide of Ru, forming the upper electrode, is formed by the sputtering process or CVD process.

The barrier film, lower electrode-forming conductive film, ferroelectric material layer 2, and upper electrode-forming conductive film are patterned by dry etching, or ferroelectric material layer 2 and upper electrode-forming conductive film are patterned for the case having the lower electrode 3 already formed thereunder, to thereby form the capacitor element 1 having the upper electrode 4, lower electrode 3, and the ferroelectric material layer 2 placed between these electrodes.

A second insulating interlayer is then formed on thus-formed capacitor element 1, plugs electrically connected to the upper electrode 4 are formed in the second insulating interlayer, and interconnects electrically connected to the plus are formed.

Next paragraphs will describe preferable Examples of the present embodiment.

### EXAMPLE 1

On a Ru film of 100 nm thick as a conductive film for the lower electrode, a film of the initial nuclei (PTO), buffer layer (PTO) and ferroelectric material layer 2 (PZT) were formed by the MOCVD process as described below, using the source materials listed in the next, at a substrate temperature of 490° C. and a film formation pressure of 1 Torr (133 Pa), and thereafter, an Au film of 100 nm thick was formed as the upper electrode 4 by the vacuum evaporation process, so as to avoid any thermal treatment effects ascribable to the formation of the upper electrode.

Pb source: a solution of lead bis-dipivaloyl methanate (Pb(DPM)₂) dissolved in an organic solvent (0.1 mol/L).

Ti source: a solution of titanium diisopropoxy dipivaloyl methanate (Ti(OiPr)₂(DPM)₂) dissolved in an organic solvent (0.3 mol/L).

Zr source: a solution of zirconium isopropoxy tris-dipivaloyl methanate (Zr(OiPr)(DPM)₃) dissolved in an organic solvent (0.1 mol/L).

oxidative gas: nitrogen dioxide (NO₂).

The Pb source, Ti source and Zr source were transported in a form of solution, and supplied to the vacuum vessel after being gasified by a gasifier (supplied based on so-called liquid transfer system).

In further detail with respect to Example 1, the Pb source (0.2 ml/min) and an organic solvent (0.2 ml/min) were supplied in a gasified form together with nitrogen dioxide at a flow rate of 400 sccm for two seconds prior to formation of the initial nuclei (pretreatment process).

Next, the Pb source (0.3 ml/min) and the Ti source (0.14 ml/min) were supplied in a gasified form together with nitrogen dioxide at a flow rate of 400 sccm for 20 seconds, to thereby form the film of the initial nuclei (crystal nuclei) of 3 nm thick (initial nuclei formation process). The initial nuclei thus formed had the compositional ratio (Ti)/(Pb)((B)/(A)) of 1.0.

Then, the Pb source (0.3 ml/min) and the Ti source (0.08 ml/min) were supplied in a gasified form together with nitrogen dioxide at a flow rate of 400 sccm for 20 seconds, to thereby form the buffer layer of 2 nm thick (buffer layer formation process). The buffer layer thus formed had the compositional ratio (Ti)/(Pb)((B)/(A)) of 0.6.

The Pb source of a predetermined flow rate, the Ti source (0.1 ml/min) and the Zr source (0.2 ml/min) were supplied in a gasified form together with nitrogen dioxide at a flow rate of 400 sccm for 900 seconds, to thereby form the ferroelectric material layer 2 of 0.230 nm thick. The flow rate of the Pb source herein was varied by a 0.01 ml/min pitch within a range from 0.3 ml/min to 0.36 ml/min so as to vary Pb/(Zr+Ti) ratio (ferroelectric material layer formation process).

Then, an Au film of 100 nm thick was formed as the upper electrode (used for verifying electrical characteristics of the capacitor) by the vacuum evaporation process.

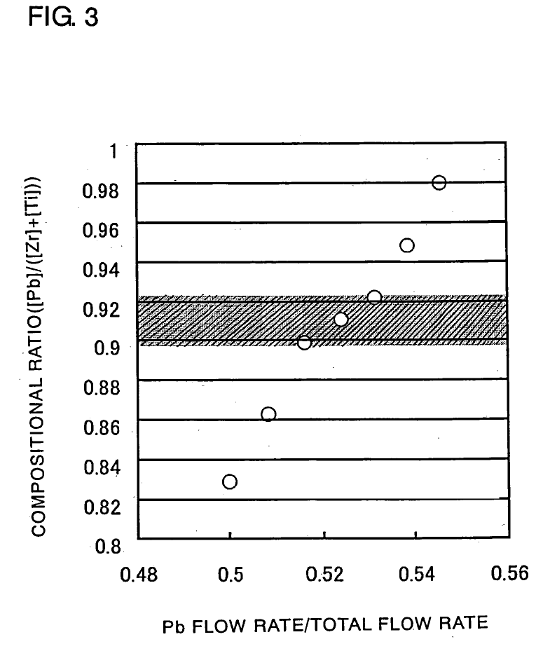

FIG. 3 is a drawing showing relations between compositional ratio (Pb)/((Zr)+(Ti)) of the ferroelectric material layer 2 obtained in Example 1 and ratio of flow rates of source materials in the ferroelectric material layer formation process. The ratio of flow rates herein expresses a ratio of Pb flow rate and the total flow rate, or in other words, Pb flow rate/(Pb flow rate+Ti flow rate+Zr flow rate), wherein the graph of FIG. 3 indicates larger ratio of Pb flow rate in the rightward direction. In FIG. 3, a region where ratio of increase in the compositional ratio (Pb)/((Zr)+(Ti)) with respect to increase in the ratio of Pb flow rate is relatively small (i.e., the self-control region) are indicated by hatching.

It is found from FIG. 3 that the self-control region resides in a range of the compositional ratio (Pb)/((Zr)+(Ti)) from 0.90 to 0.92.

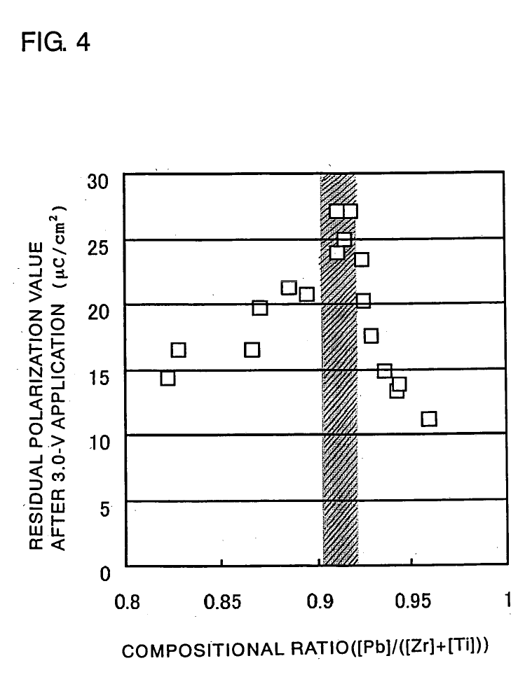

FIG. 4 is a drawing showing relations between the residual polarization value (in μC/cm²) of the ferroelectric material layer 2 obtained in Example 1 and the compositional ratio (Pb)/((Zr)+(Ti)). The residual polarization value herein is a value at an intersection, with Y axis, of a hysteresis (single-shot hysteresis) curve, obtained under bipolar single-shot voltage sweeping at ±3 V, of a device having the upper electrode 4 formed on the ferroelectric material layer 2. Also in FIG. 4, the self-control region is indicated by hatching.

It is found from FIG. 4 that the residual polarization value (capacitor characteristics) is distinctively improved in the self-control region (compositional ratio (Pb)/((Zr)+(Ti))=0.90 to 0.92) as compared with that in other regions.

It is also found that the residual polarization value becomes maximum in particular under a compositional ratio ((Pb)/((Zr)+(Ti))=0.90) which corresponds to a point where a value of the compositional ratio (Pb)/((Zr)+(Ti)) phases into the self-control region from the smaller value region (i.e., the lower limit value in the self-control region).

It is also found that the residual polarization value sharply degrades beyond the self-control region. In other words, the compositional ratio in the prior art results in degradation of the residual polarization value.

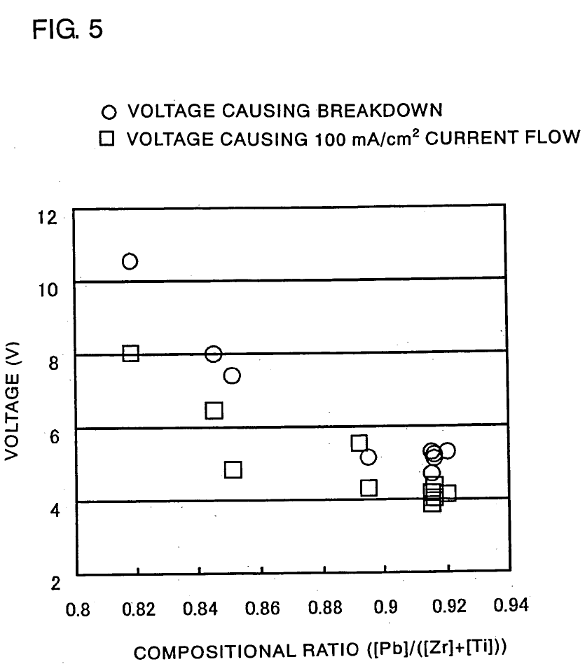

FIG. 5 is a drawing showing breakdown voltage (voltage resistance) of a device having the upper electrode 4 formed on the ferroelectric material layer 2 obtained in Example 1, applied with a positive voltage on the upper electrode 4, and voltage under which a current density of 1×10⁻¹ A is obtained, in relation with the compositional ratio (Pb)/((Zr)+(Ti)).

It is found from FIG. 5 that the voltage resistance improves in the region where the compositional ratio (Pb)/((Zr)+(Ti)) falls to the lower limit of the self-control region ((Pb)/((Zr)+(Ti))≦0.90) or below.

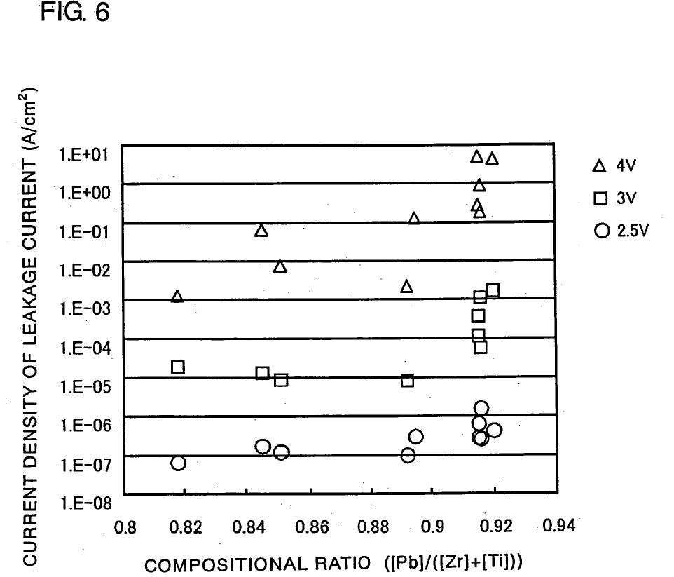

FIG. 6 is a drawing showing relations between current values (leakage current) of a device having the upper electrode 4 formed on the ferroelectric material layer 2 obtained in Example 1, applied with a positive voltage on the upper electrode 4 side, and the compositional ratio (Pb)/((Zr)+(Ti)). The current values were studied in three ways under an applied voltage of 2.5 V (◯), 3 V (□) and 4 V (Δ).

It is known from FIG. 6 that the leakage current is suppressed in the region where the compositional ratio (Pb)/((Zr)+(Ti)) falls to the lower limit of the self-control region or below.

Considering the above, it is found that the compositional ratio (Pb)/((Zr)+(Ti)) is preferably adjusted within the self-control region (0.90≦(Pb)/((Zr)+(Ti))≦0.92 for Example 1) in view of obtaining a desirable residual polarization value, and the compositional ratio (Pb)/((Zr)+(Ti)) is preferably adjusted to the lower limit of the self-control region or below ((Pb)/((Zr)+(Ti))≦0.90) in view of obtaining a desirable I-V characteristics.

### EXAMPLE 2

Example 2 will be explained in the following.

Example 2 largely differs from the foregoing Example 1 in two points. One is that the film formation temperature is high (530 degrees C. on the substrate temperature basis) as compared with Example 1. The other is that the formation process of the buffer layer is omitted (that is, the capacitor element 1 in Example 2 has no buffer layer).

In Example 2, on the Ru film of 100 nm thick (same as that in Example 1) as a conductive film employed for the lower electrode, the film of the initial nuclei (PTO) and ferroelectric material layer 2 (PZT) were formed based on the MOCVD process using the source materials same as those in Example 1, at a substrate temperature of 530 degrees C. and a film formation pressure of 1 Torr (same as those in Example 1), and thereafter an Au film of 100 nm thick was formed as the upper electrode 4 by the vacuum evaporation process.

In further detail with respect to Example 2, the Pb source (0.2 ml/min) and an organic solvent (0.2 ml/min) were supplied in a gasified form together with nitrogen dioxide at a flow rate of 400 sccm for 5 seconds prior to formation of the initial nuclei (pretreatment process). That is, the duration of the supply time of the gasified sources was increased to 5 seconds from 2 seconds in Example 1.

The Pb source (0.3 ml/min) and the Ti source (0.11 ml/min) were supplied in a gasified form together with nitrogen dioxide at a flow rate of 400 sccm for 20 seconds, to thereby form the film of the initial nuclei (crystal nuclei) of 3 nm thick (initial nuclei formation process). That is, the flow rate of the Ti source was decreased to 0.11 ml/min from 0.14 ml/min in Example 1. The initial nuclei thus formed had the compositional ratio (Ti)/(Pb)((B)/(A)) of 1.0.

The Pb source of a predetermined flow rate, the Ti source (0.15 ml/min) and the Zr source (0.32 ml/min) were supplied in a gasified form together with nitrogen dioxide at a flow rate of 400 sccm for 600 seconds, to thereby form the ferroelectric material layer of 230 nm thick. The flow rate of the Pb source herein was varied by a 0.01 ml/min to 0.5 ml/min pitch within a range from 0.4 ml/min to 0.68 ml/min by use of MFC (Mass Flow Controller) so as to vary Pb/(Zr+Ti) ratio (ferroelectric material layer formation process). That is, the flow rate of the Zr source, the supply time of the gasified sources, and variable range of the flow rate of the Pb source are altered from those in Example 1.

Next, an Au film of 100 nm thick was formed as the upper electrode (used for verifying electrical characteristics of the capacitor) by the vacuum evaporation process (similarly to as described in Example 1).

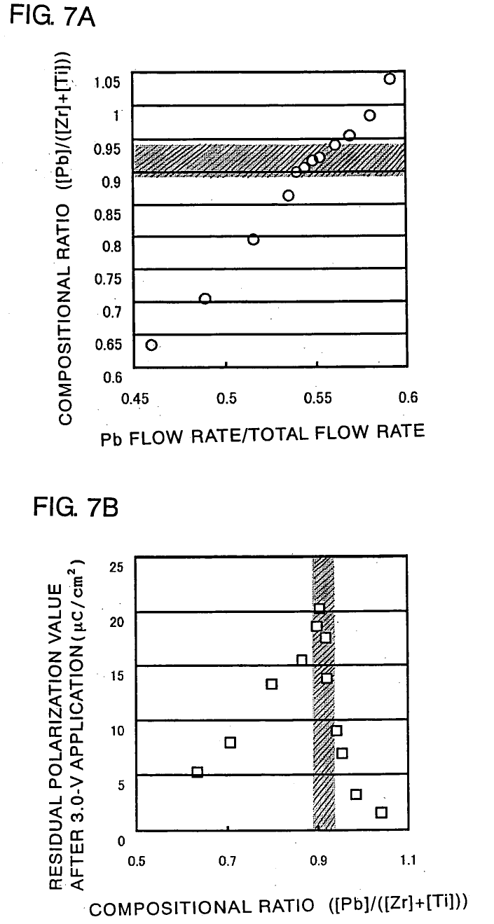

FIGS. 7A and 7B are drawings showing characteristics of the ferroelectric material layer 2 obtained in Example 2. Of these, FIG. 7A is a drawing showing relations between the compositional ratio (Pb)/((Zr)+(Ti)) of the ferroelectric material layer 2 and ratio of flow rates of the source materials in the ferroelectric material layer formation process, similarly to FIG. 3. On the other hand, FIG. 7B is a drawing showing relations between the residual polarization value (in μC/cm²) of the ferroelectric material layer 2 and the compositional ratio (Pb)/((Zr)+(Ti)), similarly to FIG. 4. Also in FIGS. 7A and 7B, the self-control regions are indicated by hatching. The self-control region in FIGS. 7A and 7B (Example 2) falls within a range of the compositional ratio (Pb)/((Zr)+(Ti)) from 0.90 to 0.95.

It is known from FIGS. 7A and 7B, that the residual polarization value (capacitor characteristics) can largely be improved in the self-control region similarly to Example 1, although the compositional ratio (Pb)/((Zr)+(Ti)) giving the self-control region in Example 2 differs from that in Example 1.

It is also found that the residual polarization value becomes maximum under a compositional ratio ((Pb)/((Zr)+(Ti))=0.90) which corresponds to a point where a value of the compositional ratio (Pb)/((Zr)+(Ti)) phases into the self-control region from the smaller value region (i.e., the lower limit value in the self-control region).

It is still also found that the residual polarization value sharply degrades beyond the self-control region.

It is obvious from Example 1 and Example 2, that the compositional ratio ((Pb)/((Zr)+(Ti))) under discussion depends neither on the film formation temperature (490 degrees C. in Example 1 but 530 degrees C. in Example 2), nor on the state of formation of the initial interface (the buffer layer was formed in Example 1 but not in Example 2).

### EXAMPLE 3

Next paragraphs will describe Example 3.

The foregoing Example 1 and Example 2 dealt with the capacitor element 1 using Au as the upper electrode 4, whereas Example 3 will describe the capacitor element 1 using an oxide of Ru as the upper electrode 4.

In Example 3, the capacitor element 1 was formed under similar conditions with Example 1, except for that a film of oxide of Ru is formed as the upper electrode 4.

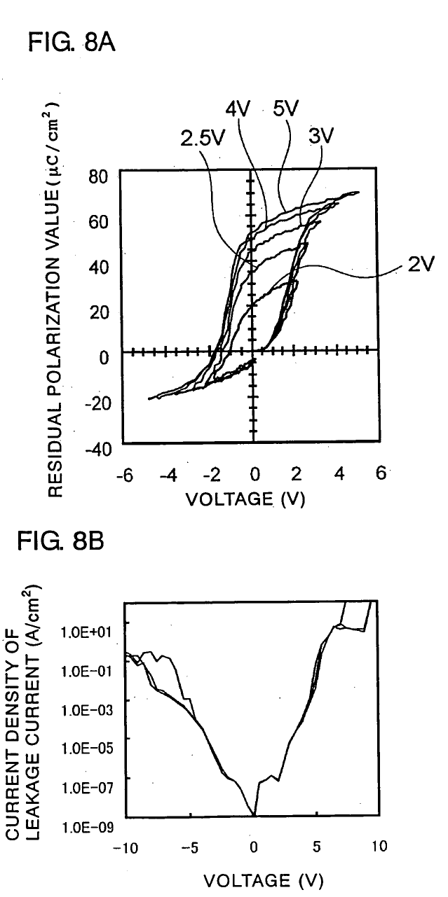

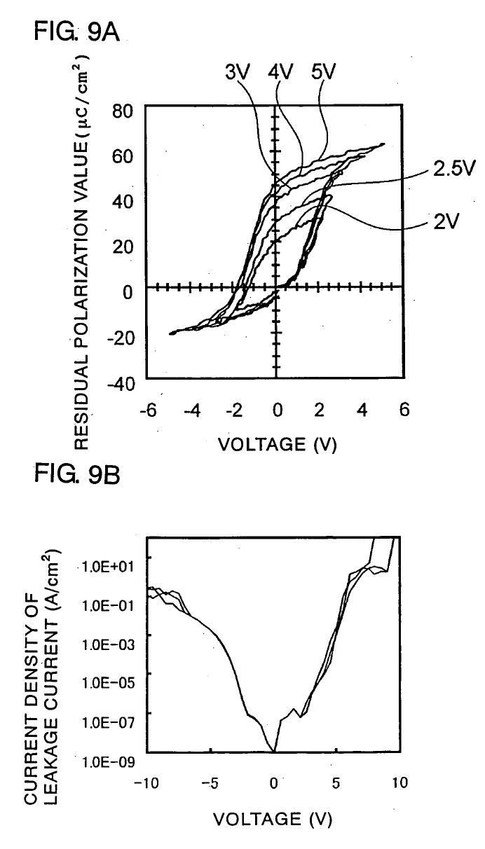

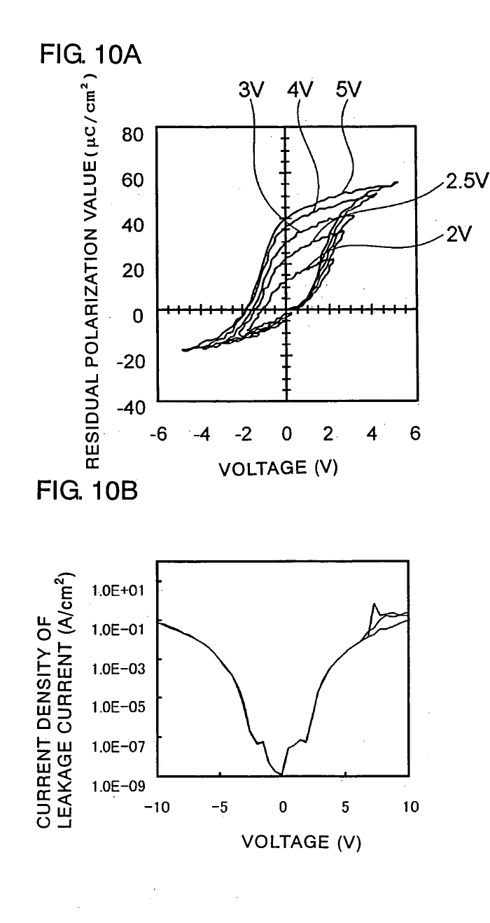

FIG. 8A to FIG. 10B are drawings showing hysteresis characteristics (FIG. 8A, FIG. 9A, FIG. 10A) and I-V characteristics (FIG. 8B, FIG. 9B, FIG. 10B) of the capacitor element 1 formed in Example 3. Of these, FIGS. 8A and 8B corresponds to a compositional ratio (Pb)/((Zr)+(Ti)) of 0.892, FIGS. 9A and 9B to a compositional ratio (Pb)/((Zr)+(Ti)) of 0.851, and FIGS. 10A and 10B to a compositional ratio (Pb)/((Zr)+(Ti)) of 0.818, respectively. It is to be noted herein that the hysteresis characteristics shown in FIG. 8A, FIG. 9A and FIG. 10A are expressed by overlaying the hysteresis characteristics obtained under bipolar single-shot voltage sweeping at ±2V, ±2.5V, ±3V, ±4V and ±5V. The I-V characteristics were measured three times, and data obtained from each run of measurement are shown in an overlaid manner in FIG. 8B, FIG. 9B and FIG. 10B.

As shown in FIG. 8A to FIG. 10B, Example 3 is found to be successful in obtaining a desirable residual polarization value at around a compositional ratio (Pb)/((Zr)+(Ti)) of 0.90, similarly to the case of the upper Au electrode, and more specifically, it is found that a more better residual polarization value can be obtained as the compositional ratio (Pb)/((Zr)+(Ti)) comes closer to 0.90. Among the cases shown in FIG. 8A to FIG. 10B, the residual polarization value gradually increases in the order of FIGS. 10A and 10B, FIGS. 9A and 9B, FIGS. 8A and 8B.

It is also confirmed that the I-V characteristics become more desirable as the compositional ratio (Pb)/((Zr)+(Ti)) becomes more smaller than 0.90. In other words, the I-V characteristics gradually improve in the order of FIGS. 8A and 8B, FIGS. 9A and 9B, FIGS. 10A and 10B.

It is confirmed, based on Example 1, Example 2 and Example 3, that the compositional ratio ((Pb) ((Zr)+(Ti))) under discussion does not depend on the upper electrode material (Au is employed for the upper electrode in Example 1 and Example 2, whereas an oxide of Ru is employed in Example 3).

### EXAMPLE 4

Example 4 will be explained in the next.

On a Ru film of 100 nm thick as a conductive film employed for the lower electrode, the film of the initial nuclei (PTO) and ferroelectric material layer 2 (PZT) were formed based on the MOCVD process using the source materials listed below, and thereafter the film of oxide of Ru of 100 nm thick was formed as the upper electrode 4.
Pb source: lead bis-dipivaloyl methanate (Pb(DPM)₂);
Ti source: titanium isopropoxide (Ti(OiPr)₄);
Zr source: zirconium butoxide (Zr(OtBu)₄); and
oxidative gas: nitrogen dioxide (NO₂).

The Pb source, Ti source, and Zr source were supplied to a vacuum chamber after being gasified directly from the solids or liquids (supplied based on so-called solid sublimation system).

In further detail with respect to Example 4, prior to the formation of the initial nuclei, the Pb source at a flow rate of 0.18 sccm was supplied together with nitrogen dioxide at a flow rate of 20 sccm for 20 seconds, at a substrate temperature of 330 degrees C. and a film formation pressure of 50 mTorr (6.65 Pa) (pretreatment process).

Then, under the same temperature and pressure, the Ti source at a flow rate of 0.24 sccm was kept for 10 seconds, to thereby form a film of the initial nuclei (crystal nuclei) of 2 nm thick (initial nuclei formation process). The initial nuclei thus formed had the compositional ratio (Ti)/(Pb)((B)/(A)) of 1.0.

Further, the substrate temperature is altered to 430 degrees C., while keeping the pressure unchanged from that in the initial nuclei formation process, the supply conditions were altered and stabilized as Pb source: 0.18 sccm, Ti source: 0.14 sccm, Zr source: 0.045 sccm, and nitrogen dioxide 50 sccm, the sources were then supplied for 1250 seconds, to thereby form the ferroelectric material layer of 230 nm thick (ferroelectric material layer formation process).

That is, Example 4 largely differs from Example 1 in that the film formation pressure is reduced (1 Torr to 0.05 Torr).

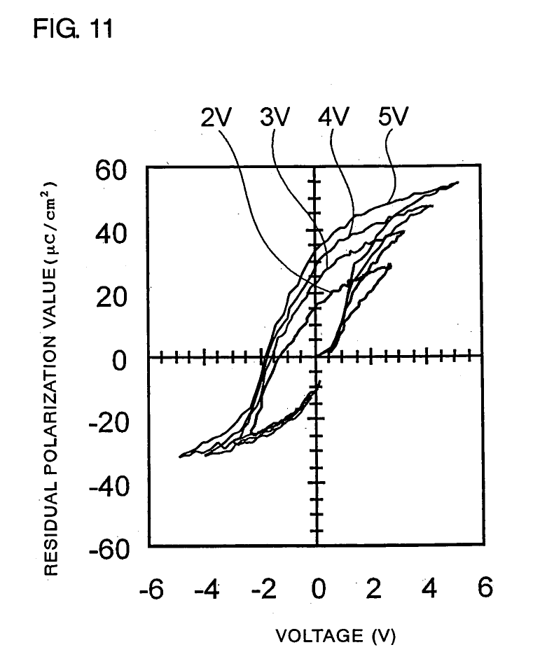

FIG. 11 is a drawing showing a hysteresis characteristic of the residual polarization value of the capacitor element 1 obtained in Example 4. It is to be noted that FIG. 11 is expressed by overlaying the hysteresis characteristics obtained under bipolar single-shot voltage sweeping at ±2.5 V, ±3.0 V, ±4.0 V and ±5.0 V.

It is confirmed from Example 4 that ferroelectricity can be obtained also under a film formation pressure of 50 mTorr, and an A/B ratio of 0.93, as shown in FIG. 11.

Next paragraphs will describe results of our investigations into why the self-control region of the composition in the present embodiment becomes smaller than the stoichimetric ratio.

First of all, essential points which largely differ from those in the prior art are as follows:
1. Higher in the film formation pressure; and
2. lower electrode 3 composed of Ru.

(1) Discussion on Difference in the Film Formation Pressure

The film formation pressure of the ferroelectric material layer in the prior art was 0.01 Torr or around. On the contrary, the film formation pressure in the present embodiment is adjusted to 0.05 to 1.0 Torr or around, which is higher than that in the prior art.

The gas-phase reactions become more likely to be carried out under such relatively high film formation pressure, and this results in formation of microcrystals of PbO, and makes PbO less likely to re-vaporize.

The PZT film having a stoichiometric composition (compositional ratio (A)/(B)=1.0) formed typically at a film formation pressure of 1.0 Torr will therefore have an excessive content of PbO based on the reason described in the above. That is, (A)/(B)=1.0 holds based on the total including PbO not bound to Ti or Zr.

It is considered that the PZT film, despite apparently having the stoichiometric composition, causes degradation in the PZT ferroelectricity (lowering in the residual polarization value) and degradation in the I-V characteristics (increase in the leakage current), due to paraelectric PbO contained therein.

Considering the above, it was confirmed from our extensive investigations into the compositional region of PZT smaller than the stoichiometric composition ((A)/(B)=1.0), while adjusting the film formation pressure as high as 1.0 Torr as described in the above, that the self-control region of the composition appears at around (A)/(B)=0.9, for example, wherein the ferroelectricity and I-V characteristics of PZT can be improved.

(2) Discussion on Difference in the Lower Electrodes

The lower electrode used in the prior art was made of Pt.

Most essential point in the formation of a Perovskitic metal oxide dielectric film such as PZT on electrodes such as being composed of Pt, Ir or Ru resides in formation of Perovskitic crystal nuclei on a substrate of Pt, Ir, Ru or the like having different crystal structures.

During growth of the crystal nuclei, concentrations of precursors of the compositional elements on the surface of the electrode are determined by the source decomposition efficiency and adhesion coefficient on the electrode, and diffusion property thereof into the electrode. The crystal nuclei can be produced only when the surface concentrations are adjusted to the stoichiometric ratio of a film of substance to be formed.

In particular, the element A (e.g., Pb) which occupies lattice A (site A) is readily alloyed with the conductive material composing the electrode, and is likely to diffuse into the electrode. It is therefore necessary to supply the element A in a slightly larger amount during formation, in order to prevent deficiency of the element A in the vicinity of the interface due to the diffusion.

It is necessary herein to supply Pb, having a larger reactivity with Pt, in an amount larger than those of Ir and Ru.

In contrast to this, the lower electrode (Ru electrode) employed in the present embodiment is less causative of the diffusion of Pb on the surface of the electrode as compared with the Pt electrode, so that it is no more necessary to increase the amount of supply of Pb during the formation of the crystal nuclei. It is otherwise considered that Ru less causative of the Pb diffusion is more likely to allow PbO to crystallize thereon, and this consequently raises a need of reducing the compositional ratio (A)/(B) of PZT.

It is to be noted herein that the crystal nuclei (PTO) is employed in this proposal, and it is confirmed that the optimum composition thereof is Pb/Ti=1.0, which is a stoichiometric ratio of PTO. Therefore the optimum composition of PZT formed thereon should be the stoichiometric composition similarly to the crystal nuclei. The optimum composition for obtaining a desired capacitor characteristics is, however, smaller than the stoichiometric ratio, so that it is supposed that the difference in the electrodes be irresoluble on the variance in the optimum composition of PZT for this case.

As a conclusion derived from the above discussions (1) and (2), an essential factor is supposed to reside in the higher film formation pressure as explained in (1).

In particular, under the film formation conditions specific to the present embodiment (lower film formation temperature and higher pressure as compared with those in the prior art), it is supposed that PbO taken into the PZT film is made less likely to eliminate, and due to such non-eliminable PbO, the characteristics cannot be improved even if PZT is adjusted to have the stoichiometric ratio of (A)/(B)=1.0.

The discovery of the present inventors is that the optimum composition not affected by PbO resides in the region smaller than the stoichiometric ratio, and that the self-control region of the composition can exist even in the above-described film formation conditions, and thereby the characteristics can be improved. In other words, it is found that a composition suitable for attaining the desired characteristics shall exist at the lower limit of the self-control region or below, even if it is short of the stoichiometric ratio.

As has been described in the above, the capacitor element 1 of the present embodiment, employing the ferroelectric material layer (ferroelectric material) 2 having Perovskitic crystal structure expressed by the general formula ABO₃, is successful in obtaining a desirable residual polarization value, because the compositional ratio (A)/(B) of the element A and element B contained in the ferroelectric material layer 2 is adjusted within the range satisfying the formula (1). This is also successful in obtaining desirable I-V characteristics.

In particular, a further desirable residual polarization value can be obtained by forming the film of the ferroelectric material layer 2 while adjusting the compositional ratio (A)/(B) within the range satisfying the formula (2), that is, adjusting it to the upper limit of the self-control region or below.

In particular, a further desirable I-V characteristics can be obtained by forming the film of the ferroelectric material layer 2 while adjusting the compositional ratio (A)/(B) within the range satisfying the formula (3), that is, adjusting it to the lower limit of the self-control region or below.

It is still also possible to improve the mass-productivity (throughput (film formation rate) and in-plane uniformity) by raising the film formation pressure as compared with that in the prior art.

Although the present embodiment has explained the exemplary case where the ferroelectric material is used for the capacitor element, the present invention is by no means limited thereto.

Although the present embodiment has explained the exemplary case where the capacitor element of the present invention is adopted to the semiconductor memory device, the memory device may not be semiconductor memory device (having the substrate not composed of a semiconductor).

It is apparent that the present invention is not limited to the above embodiments, that may be modified and changed without departing from the scope and spirit of the invention.

1. A semiconductor device using a ferroelectric material having Perovskitic crystal structure expressed by general formula ABO₃, said ferroelectric material having a compositional ratio (A)/(B) of element A and element B contained therein, set within a range satisfying the formula (1):
0.65≦(A)/(B)<1.0 (1)

2. The semiconductor device according to claim 1, wherein said compositional ratio (A)/(B) is set within a range satisfying the formula (2):
0.65≦(A)/(B)≦0.95 (2)

3. The semiconductor device according to claim 1, wherein said compositional ratio (A)/(B) is set within a range satisfying the formula (3):
0.65≦(A)/(B)≦0.90 (3)

4. The semiconductor device according to claim 1, wherein said ferroelectric material comprises PZT which contains lead (Pb) as said element A, and contains zirconium (Zr) and titanium (Ti) as said element B.

5. A method of fabricating a semiconductor device using a ferroelectric material having Perovskitic crystal structure expressed by general formula ABO₃, wherein
assuming sources of element A and element B, supplied during film formation of said ferroelectric material, as a source A and a source B, respectively, and amounts of supply of said element A and said element B as amount A and amount B, respectively,
a film of said ferroelectric material being formed while setting ratio of supply amount of said source A to the total of supply amounts of said source A and said source B “amount A/(amount A+amount B)” to a value not higher than the upper limit of a self-control region where ratio of increase in the compositional ratio (A)/(B) of said element A and said element B with respect to increase in the ratio of supply amounts “amount A/(amount A+amount B)” is relatively small.

6. The method of fabricating a semiconductor device according to claim 5, wherein said film of said ferroelectric material is formed while setting said ratio of supply amounts “amount A/(amount A+amount B)” to a value not higher than the lower limit of said self-control region.

7. The method of fabricating a semiconductor device according to claim 5, wherein said film of said ferroelectric material is formed by a vapor-phase growth process under a pressure condition of not less than 6.65 Pa and not more than 532 Pa.

8. The semiconductor device according to claim 1, being a capacitor element which comprises a ferroelectric material layer composed of said ferroelectric material, and a lower electrode and an upper electrode arranged so as to hold said ferroelectric material layer in between.

9. The semiconductor device according to claim 8, wherein said lower electrode is composed of ruthenium (Ru).

10. The semiconductor device according to claim 8, wherein said upper electrode is composed of ruthenium oxide.

11. The semiconductor device according to claim 8, wherein said lower electrode has a film composed of at least any one material selected from platinum (Pt), iridium (Ir), ruthenium (Ru) and oxides of these elements, formed at least on the surface thereof for the ferroelectric material layer side.

12. The semiconductor device according to claim 8, wherein said upper electrode has a film composed of at least any one material selected from platinum (Pt), iridium (Ir), ruthenium (Ru) and oxides of these elements, formed at least on the surface thereof for the ferroelectric material layer side.

13. The method of fabricating a semiconductor device according to claim 5, wherein
said semiconductor device is a capacitor element which comprises a ferroelectric material layer composed of said ferroelectric material, and a lower electrode and an upper electrode arranged so as to hold said ferroelectric material layer in between.

14. The method of fabricating a semiconductor device according to claim 13, comprising:
forming, on said lower electrode, a film of initial nuclei containing at least one metal element same as a metal element composing said ferroelectric material layer; and
forming said ferroelectric material layer on said initial nuclei,
carried out in this order.

15. The method of fabricating the semiconductor device according to claim 13, comprising:
forming, on said lower electrode, a film of initial nuclei containing at least one metal element same as a metal element composing said ferroelectric material layer;
forming, on said initial nuclei, a buffer layer containing at least one metal element same as a metal element contained in both of said initial nuclei and said ferroelectric material layer, in a ratio larger than that in said initial nuclei; and
forming said ferroelectric material layer on said buffer layer,
carried out in this order.

16. The method of fabricating a semiconductor device according to claim 15, wherein said film of initial nuclei is formed so as to contain said element A and said element B.

17. The method of fabricating a semiconductor device according to claim 15, wherein said buffer layer is formed so as to contain said element A and said element B.

18. The method of fabricating a semiconductor device according to claim 16, wherein a film of said initial nuclei and said buffer layer are formed using lead titanium oxide (PTO) containing lead (Pb) as said element A and titanium (Ti) as said element B.

19. The method of fabricating a semiconductor device according to claim 17, wherein said buffer layer is formed so as to have a ratio of content of said element A larger than that of said initial nuclei.

20. The method of fabricating a semiconductor device according to claim 16, wherein a film of said initial nuclei is formed so that the compositional ratio (B)/(A) of said element A and said element B contained therein satisfies the formula (6):
0.8≦(B)/(A)≦1.2 (6)

21. The method of fabricating a semiconductor device according to claim 17, wherein said buffer layer is formed so that the compositional ratio (B)/(A) of said element A and said element B contained therein satisfies the formula (4):
0.2≦(B)/(A)≦1.0 (4)

22. The method of fabricating a semiconductor device according to claim 15, wherein a film of said initial nuclei is formed so that the compositional ratio (B)/(A) of said element A and said element B contained therein satisfies the formula (6); and
said buffer layer is formed so that the compositional ratio (B)/(A) of said element A and said element B contained therein satisfies the formula (4):
0.8≦(B)/(A)≦1.2 (6)
0.2≦(B)/(A)≦1.0 (4)

23. The method of fabricating a semiconductor device according to claim 14, wherein a film of said initial nuclei is formed to a thickness of not less than 1 nm and not more than 10 nm.

24. The method of fabricating a semiconductor device according to claim 15, wherein said buffer layer is formed to a thickness of not less than 0.2 nm and not more than 10 nm.

25. The method of fabricating a semiconductor device according to claim 14, wherein a film of said initial nuclei is formed under a condition satisfying at least any one conditions at lower in the temperature, and at higher in the pressure, as compared with those in formation conditions of said ferroelectric material layer.

26. A memory device comprising the semiconductor device according to claim 8.
